(19) United States
(12) Patent Application Publication
(10) Pub. No.: US 2019/0181240 A1
(43) Pub. Date: Jun. 13, 2019

(54) METHODS FOR TRANSISTOR EPITAXIAL STACK FABRICATION

(71) Applicant: Texas Instruments Incorporated, Dallas, TX (US)

(72) Inventors: Qhalid Fareed, Plano, TX (US); Asad Mahmood Haider, Plano, TX (US)

(73) Assignee: Texas Instruments Incorporated, Dallas, TX (US)

(21) Appl. No.: 15/840,392

(22) Filed: Dec. 13, 2017

(51) Int. Cl. H01L 29/66; H01L 21/02; H01L 29/20; H01L 29/778

(52) U.S. Cl. CPC H01L 29/66462; H01L 29/66431; H01L 29/7783; H01L 29/2003; H01L 21/0254

(57) ABSTRACT

Disclosed examples provide methods for fabricating an epitaxial layer stack for a gallium nitride transistor in an integrated circuit, including forming an aluminum nitride layer (AlN) on a substrate with a predetermined resistivity in a processing chamber, forming an aluminum gallium nitride layer (AlGaN) on the AlN layer in the processing chamber, forming a surface layer on the AlGaN layer in the processing chamber, and controlling the processing chamber temperature after forming the surface layer to cool the substrate and the formed layers at a controlled rate to control wafer bow.

### BACKGROUND

Wide band gap semiconductor materials such as gallium nitride (GaN) are gaining popularity for high voltage high speed switching applications. Gallium nitride has a relatively wide band gap of 3.4 eV at room temperature compared with 1.1 eV for silicon (Si). GaN can be used to create high electron mobility transistor (HEMT) devices that use two dimensional electron gas (2DEG) accumulations in the interface between GaN and aluminum gallium nitride (AlGaN) material layers. These devices exhibit lower on-state drain-source resistance (RDSON), lower threshold voltages and higher voltage breakdown ratings than corresponding silicon transistors. Gallium nitride transistors have thus emerged as a high-performance alternative to silicon-based transistors, thanks to the technology's ability to be made allow smaller device sizes for a given on-resistance and breakdown voltage than silicon. However, GaN and silicon have significant thermal expansion coefficient mismatches. Buffer layers are used between the silicon substrate and the GaN layer to manage strain in GaN-on-Silicon technology for HEMT, heterostructure FET (HFET) or modulation-doped FET (MODFET) devices that include a junction between two materials with different band gaps (i.e., a heterojunction) as the channel instead of a doped region. Some buffer arrangements for such devices use either super lattice structures or a graded buffer structure. As breakdown voltage levels are increased for high voltage switching applications, buffer layers need to be made thicker, and thermal mismatch during buffer layer epitaxial deposition leads to wafer bowing. Wafer bow is exacerbated when depositing thicker than 4 um film stack typically required for high breakdown voltage GaN devices, and bowed wafers post GaN epi deposition cannot be processed through manufacturing line because of wafer handling and lithography problems. Moreover, high bow wafers cause excessive strain in the epitaxial stack, leading to film cracking and wafer breakage during processing.

### SUMMARY

Disclosed examples provide IC fabrication techniques, including forming an aluminum nitride layer on a substrate with a predetermined resistivity in a processing chamber, forming an aluminum gallium nitride layer on the aluminum nitride layer in the processing chamber, forming a surface layer on the aluminum gallium nitride layer in the processing chamber, and controlling the processing chamber temperature after forming the surface layer to cool the substrate and the formed layers at a controlled rate to control wafer bow. Certain examples include selecting the starting substrate having a resistivity in a predetermined range to control wafer bow and facilitate improved manufacturing yield. In certain examples, the aluminum gallium nitride layer is formed over aluminum nitride layer. In certain examples, the aluminum gallium nitride layer is formed as a multilayer with progressively reducing sublayer aluminum content and progressively increasing sublayer thickness. Certain examples include applying heat to the substrate to control the processing chamber temperature during the controlled cool down. Certain examples include providing nitrogen gas in the processing chamber while cooling the substrate to mitigate surface defects and facilitate wafer bow control. In certain examples, the relative thickness of the aluminum nitride layer, the aluminum gallium nitride layer(s) and/or the gallium nitride layer(s) are tailored to control wafer bow while meeting desired breakdown voltage ratings for a given transistor design.

### BRIEF DESCRIPTION OF THE DRAWINGS

FIG. 1 shows a flow diagram illustrating a method to fabricate an epitaxial layer stack for a transistor in an integrated circuit.

FIG. 2 is a partial sectional side elevation view showing an example integrated circuit including a GaN based epitaxial layer stack with a buffer stack and a surface layer as well as a GaN HEMT transistor.

FIG. 3 is a graph illustrating processing chamber and wafer temperatures as a function of time during epitaxial deposition processing according to the method of FIG. 1, including a controlled cool down phase after buffer stack and surface layer deposition steps.

FIG. 4 is a graph illustrating the processing chamber and wafer temperatures as a function of time during the controlled cool down phase of FIG. 3.

FIG. 5 is a simplified side elevation view showing positive wafer bow.

FIG. 6 is a simplified side elevation view showing negative wafer bow.

FIG. 7 is a graph illustrating wafer bow as a function of time during the epitaxial deposition processing and controlled cool down according to the method of FIG. 1.

FIGS. 8-12 are partial sectional side elevation views showing the integrated circuit at various stages of fabrication according to the method of FIG. 1.

FIG. 13 is a partial sectional side elevation view showing the integrated circuit of FIG. 12 with an RF source for controlled cool down.

FIG. 14 is a graph illustrating wafer bow as a function of time during the epitaxial deposition processing and subsequent controlled cool down according to the method of FIG. 1, including curves showing wafer bow for three different example starting wafer resistivity values.

### DETAILED DESCRIPTION

In the drawings, like reference numerals refer to like elements throughout, and the various features are not necessarily drawn to scale. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

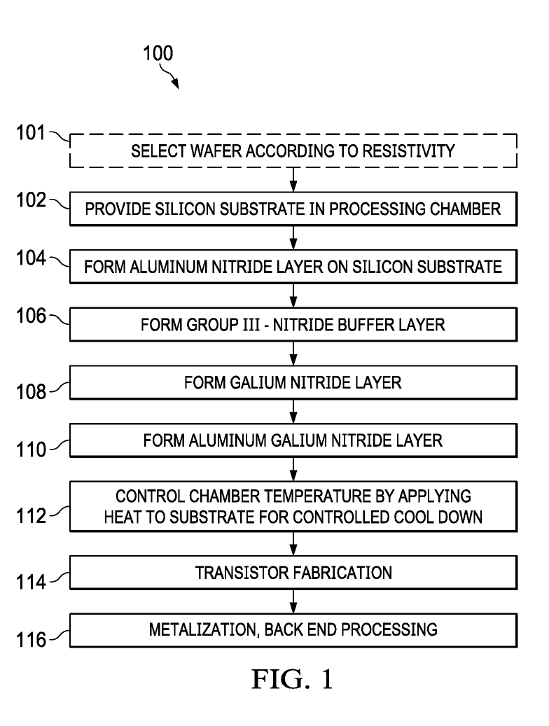

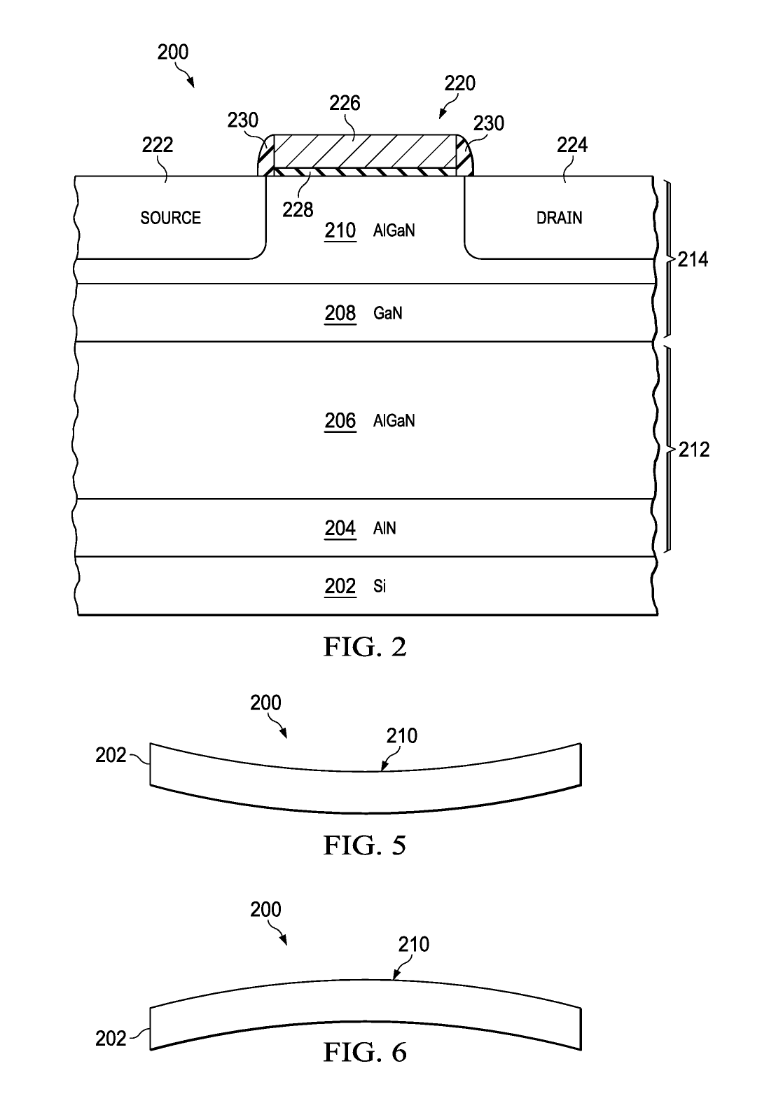

Referring initially to FIGS. 1 and 2, FIG. 1 shows an integrated circuit (IC) fabrication process or method 100 that include fabricating an epitaxial layer stack for a transistor. FIG. 2 shows an example integrated circuit 200 with a GaN transistor 220 fabricated on and in a surface layer 214 above a buffer layer 212 according to the method 100. The example method 100 provides high temperature epitaxial deposition of a layer stack for the GaN transistor 220 in a single processing chamber by forming an aluminum nitride (AlN) layer on a substrate at 104 in FIG. 1, forming an aluminum gallium nitride (AlGaN) layer on the AlN layer at 106, forming a surface layer on the AlGaN layer at 108 and 110, and implementing a controlled cool down at 112 in the processing chamber temperature after forming the surface layer. The method 100 advantageously provides advanced wafer bow control to enhance process yield by reducing post-epitaxial deposition wafer bowing and layer cracking. The process 100 and the techniques disclosed herein facilitate fabrication of high breakdown voltage transistors and corresponding increased buffer and surface layer thicknesses while controlling wafer bowing and layer cracking to provide benefits compared with prior epitaxial deposition processes and HEMT fabrication techniques. Alternate implementations include variations in the number of buffer and/or surface layers 212 and 214, as well as variations in the corresponding thicknesses of single layers or multilayer structures, and/or stoichiometry variations. Designs are possible to accommodate a variety of different breakdown voltage ratings by adjusting the thicknesses of the buffer and surface layers 212 and 214. In certain implementations, the controlled cool down processing at 112 is combined with tailored thicknesses of an AlN layer relative to a thickness of an AlGaN layer or multilayer and/or to a thickness of a GaN layer or multilayer.

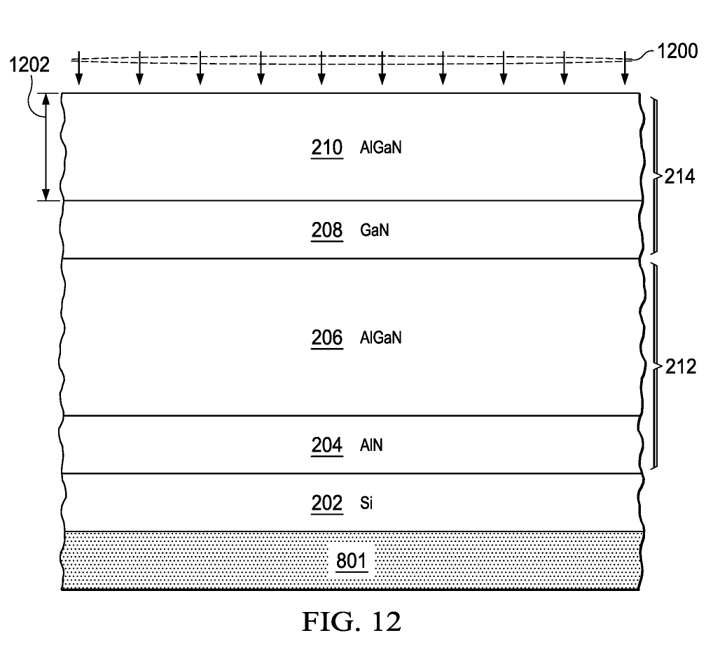

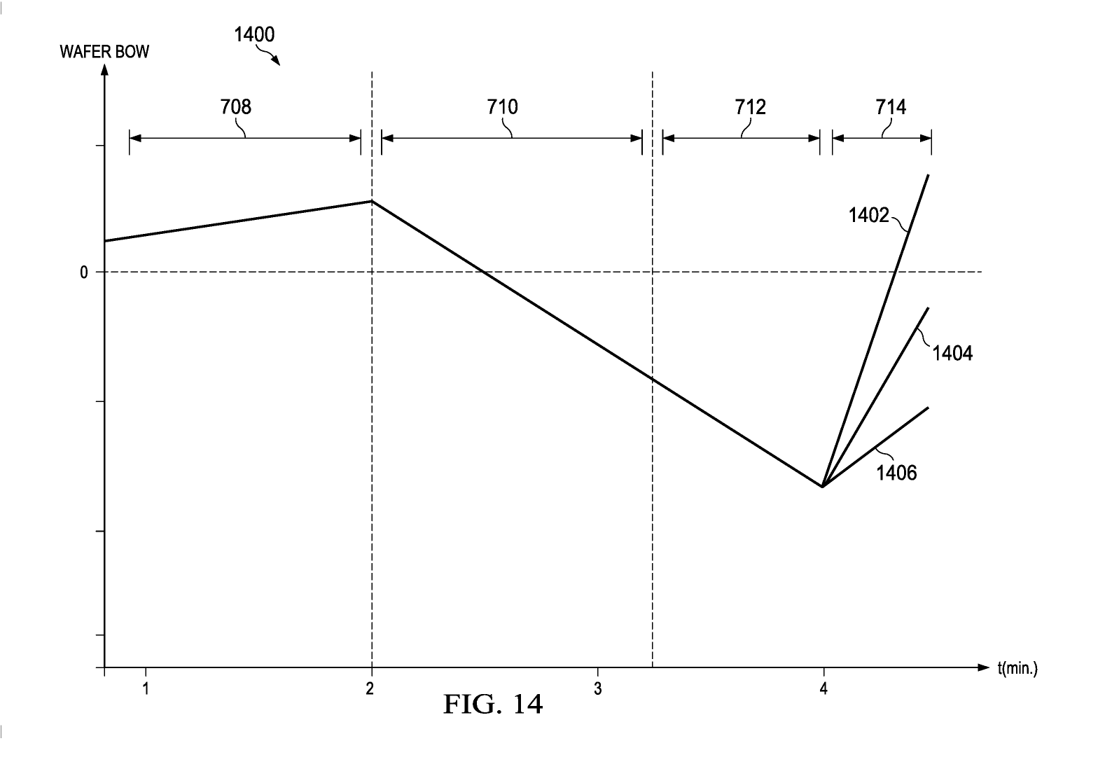

Referring also to FIGS. 8-19, the example method 100 in FIG. 1 includes providing a semiconductor substrate in a processing chamber at 102. In one example, a silicon substrate 202 is used, as shown in FIG. 8. At 104-110 in FIG. 1, the processing chamber is used to deposit or form one or more layers of the buffer layer stack 212 and the surface layer stack 214 (FIG. 2) sequentially, without removing the substrate 102 from the enclosed chamber interior. In certain implementations, moreover, the method 100 includes selecting 101 the semiconductor substrate 202 having a resistivity in a predetermined range. In one example, the processing chamber includes a carrier support structure 801 to support a cylindrical wafer substrate 202 during epitaxial deposition processing to form the buffer and surface layers 212 and 214 shown in FIG. 2. The processing chamber can include multiple carriers 801 to accommodate multiple wafers for contemporaneous processing. The processing chamber also includes environmental control apparatus (not shown) to control the wafer temperature during epitaxial deposition. In one example (e.g., FIG. 14 below), the carrier 801 is a graphite structure configured to support the substrate 202, and the chamber is equipped with an RF source to apply electrical power to apply heat to the substrate 202 via the carrier 801. The processing chamber further includes closed loop control apparatus, such as a programmed processor to implement a PID controller for profile control with ramp and soak function, etc. to control the interior temperature of the chamber and to thus control the chamber and substrate temperatures. Certain examples include suitable sensing apparatus to sense the chamber temperature either directly at the substrate 202 or otherwise in the interior of the chamber. In one example, the processing chamber controls the chamber interior temperature by application of heat to the substrate 202 via a graphite carrier structure 801.

The processing chamber also includes apparatus to provide a controlled supply of one or more gases to the interior of the chamber to implement high temperature deposition of GaN-based materials, AlN materials, etc., in combination with selective control of the material content of gases present within the interior of the chamber during deposition and controlled cool-down operations as described herein. In various implementations, the processing chamber is used to implement chemical vapor deposition process steps to form a series of stack layers, for example, using metal-organic chemical vapor deposition (MOCVD), molecular beam epitaxy (MBE), hydride vapor phase epitaxy (HVPE), etc. In one example, the processing chamber provides a controlled amount of nitrogen gas in the chamber interior at 112 while cooling the substrate 202 after the layer depositions at 104-110. During deposition processing, for example, the processing chamber applies RF energy to a graphite carrier structure 801 and can provide other thermal control mechanisms to control the processing chamber interior temperature. In certain implementations, moreover, the processing chamber is configured to control the chamber temperature following stack layer deposition in order to provide a controlled temperature change to control wafer bow. For example, the processing chamber in certain examples provides a controlled amount of heat to the substrate 202 in order to control the rate of decrease in the chamber temperature following the high temperature deposition processing.

At 104 in FIG. 1, any native oxide is removed from the upper surface of the substrate 202, and an aluminum nitride layer is formed on the substrate 102. An example is shown in FIG. 9 in which an epitaxial deposition process 900 is used to form an AlN layer 204 to a thickness 902 on an upper surface of the silicon substrate 202. In one example, the thickness 902 is approximately 0.55 μm, although any suitable thickness can be used. Moreover, as previously mentioned, the thickness of the AlN layer 204 can be tailored relative to the thicknesses of the other layers in the buffer stack 212 and/or the thicknesses of one or more of the layers of the surface layer stack 214 in order to control wafer bow. In addition, the thicknesses of the layer 204 and the other layers 206-222 can be designed or tailored in order to provide any desired breakdown voltage rating for the subsequently formed transistor 220.

The method 100 further includes forming an aluminum gallium nitride layer 206 at 106 on the aluminum nitride layer 204 in the processing chamber. The aluminum gallium nitride layer 206 can be a single layer, or a multilayer stack structure including two or more sub layers. In one example, the aluminum gallium nitride layer 206 is formed at 106 with progressively reducing sublayer aluminum content and progressively increasing sublayer thickness using a deposition process 1000 to a thickness 1002 as shown in FIG. 10. In one example, the processing at 106 includes forming a first aluminum gallium nitride sublayer, for example, 30 μm, with a first aluminum content. The first aluminum gallium nitride sublayer in one example has a stoichiometry of AlxGal-x N (x>0.6), although not a requirement of all possible implementations. This example further includes forming a second aluminum gallium nitride sublayer on the first sublayer, where the second sublayer has a larger second thickness with a smaller second aluminum content, for example approximately 1.0 μm, and the second AlGaN layer has a stoichiometry of Alx Gal-x N (0.3<x>0.6). One example aluminum gallium nitride layer processing at 106 further includes forming the third aluminum gallium nitride sublayer on the second aluminum gallium nitride sublayer in the processing chamber to a still larger third thickness (e.g., 1.30 μm) with a still smaller third aluminum content, for example, with a stoichiometry of Alx Gal-x N (0<x>0.3), . . . .

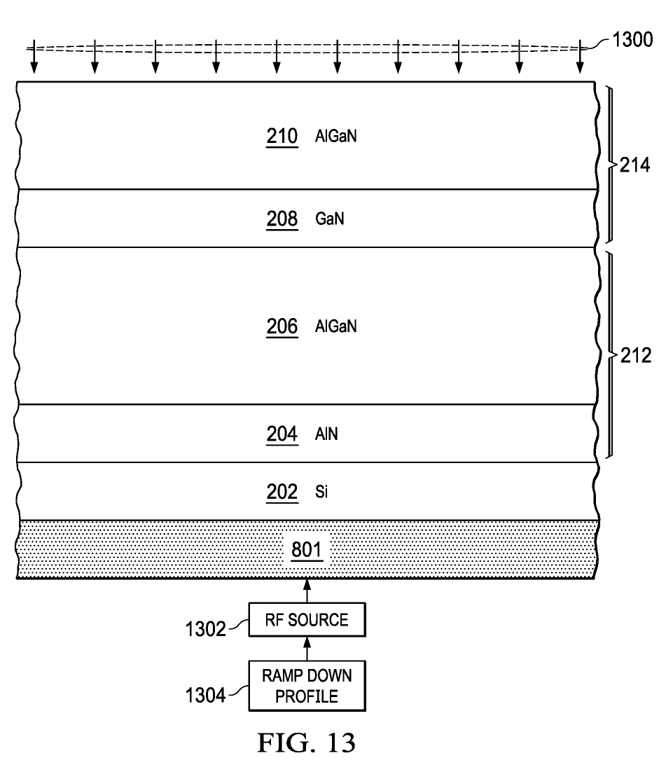

Referring also to FIGS. 11-13, the method 100 further includes forming the surface layer 214 as a multilayer structure at 108 and 110 including sub layers 208 and 210 (FIG. 2) on the aluminum gallium nitride sublayer 206. At 108, a GaN layer is formed as a multilayer structure 208 on the AlGaN layer 206 in the processing chamber. As shown in FIG. 11, the gallium nitride layer formation includes forming a GaN layer 208 to a thickness 1102 using a deposition process 1100. At 110, an aluminum gallium nitride layer 228 is formed to a thickness 1202 on the gallium nitride layer 208 using a process 1200 in the processing chamber (FIG. 12). Referring also to FIG. 13, the method 100 includes controlling the processing chamber temperature at 112 in FIG. 1 after forming the surface layer 214. The method 100 in FIG. 1 further includes fabricating at least one transistor 220 on and in the surface layer 214, and metallization and other backend processing at 122 complete the integrated circuit 200 of FIG. 2. As shown in the example of FIG. 2, the example transistor 220 in FIG. 2 includes a source 222 and a drain 224 formed through corresponding portions of the upper aluminum gallium nitride layer 210 and into an upper portion of the aluminum gallium nitride layer 210 on either side of a channel region beneath a gate structure. The transistor 220 also includes a gate dielectric or gate oxide layer 228 formed between an upper surface of a portion of the aluminum gallium nitride layer 210 and an overlying gate structure 226, as well as gate sidewall spacer structures 230. As shown in FIG. 13, the processing chamber in one example includes an RF source 1302 operatively coupled to provide power to the graphite carrier structure 801 in order to apply heat to the substrate 202 and the formed layers 204-210 during the cool down processing 1300. In addition, the processing chamber includes control apparatus to implement a ramp down profile 1304 in order to provide the control of the cooling rate for the chamber interior and the processed substrate 202 during the controlled cool down at 112 in FIG. 1.

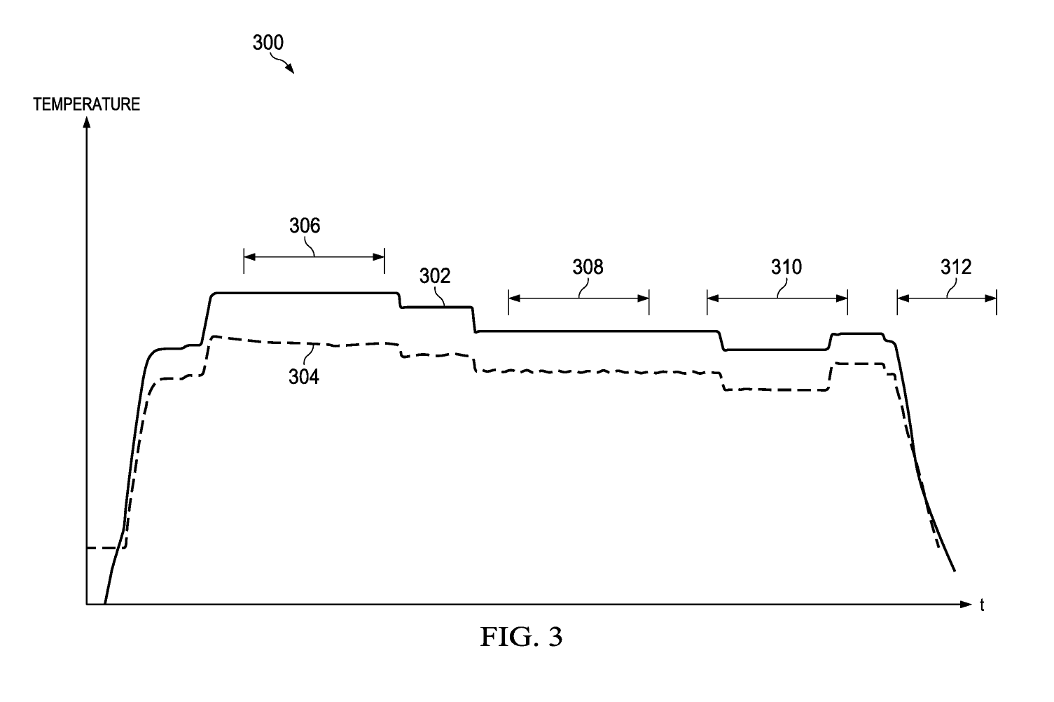

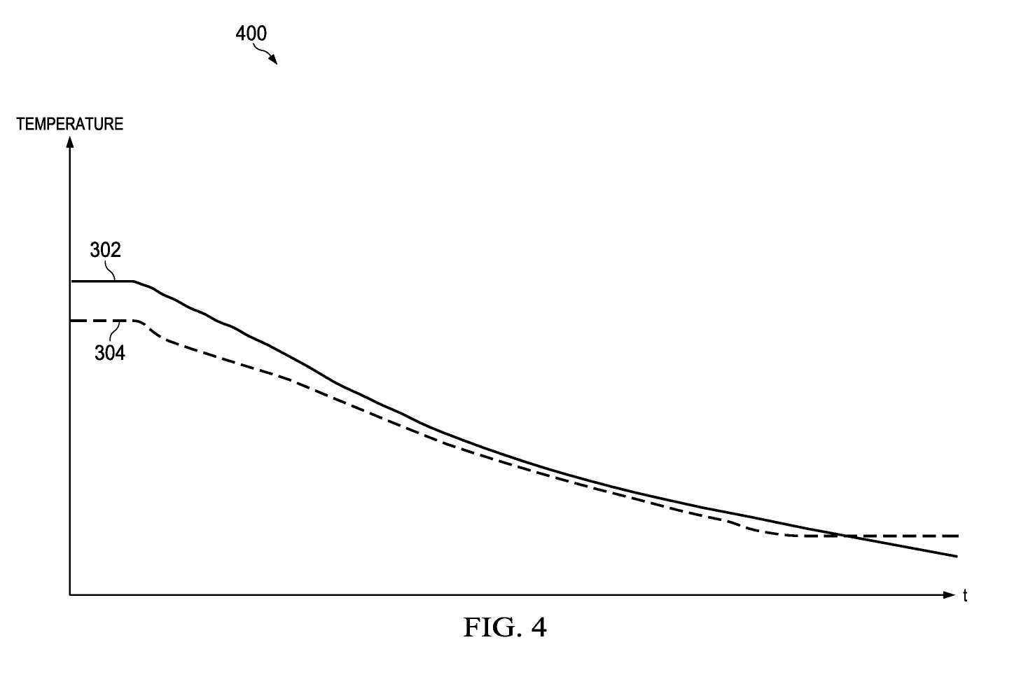

Referring also to FIGS. 3-6 the controlled cool down process at 112 in FIG. 1 facilitates wafer bow control to reduce the amount of wafer bow at the end of the buffer and surface layer deposition processing, prior to transistor fabrication and backend processing at 114, 116. A graph 300 in FIG. 3 shows the processing chamber temperature 302 and the substrate surface temperature 304 as a function of time during epitaxial deposition processing according to the method 100. The graph 400 in FIG. 4 shows the processing chamber and substrate temperature curves 302 and 304 during the controlled cool down processing phase 312 of FIG. 3. As discussed above, the formation of the buffer stack layers 212 and the surface stack layers 214 is performed in a single processing chamber at relatively high temperatures. In the illustrated example, the temperature of the processing chamber is controlled during the epitaxial deposition processing to a temperature of 1000° C. or more prior to the controlled cool down. At 306 in FIG. 3, high temperature aluminum nitride deposition is performed (e.g., 104 in FIG. 1), and the aluminum gallium nitride buffer layer 206 is formed during the time 308 in FIG. 3 (e.g., 106 in FIG. 1). At 310 in FIG. 3, the gallium nitride-based surface layers 214 are formed (108 and 110 in FIG. 1). Thereafter, at 312, the controlled cool down processing phase is performed (112 in FIG. 1) after the buffer stack and surface layer deposition steps.

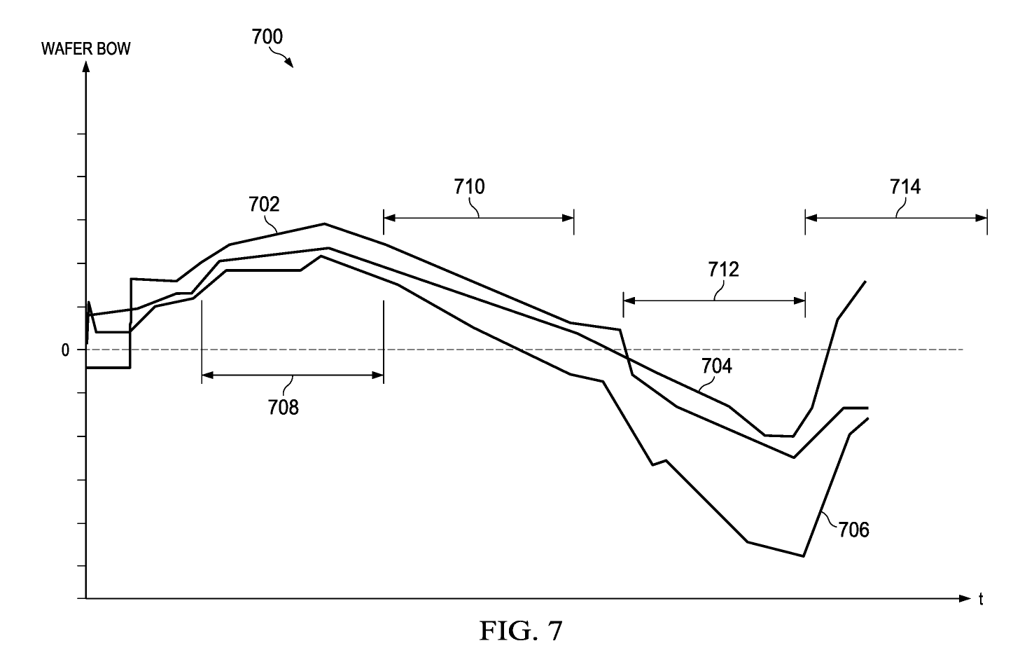

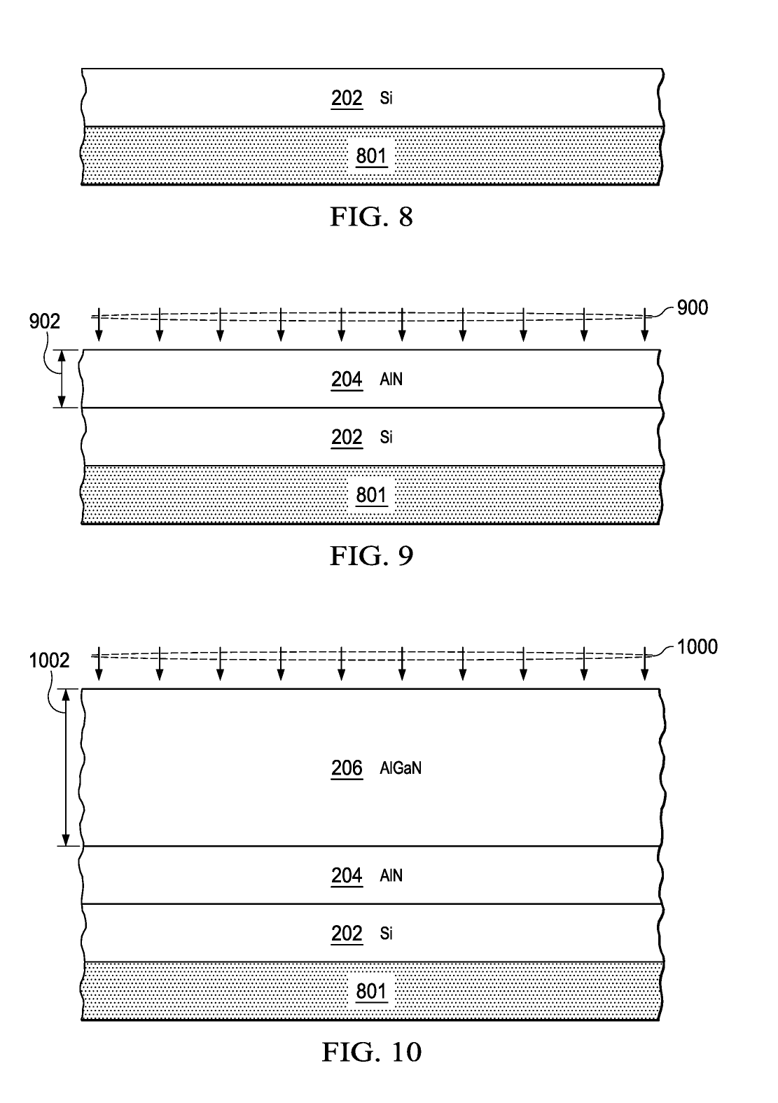

Referring also to FIGS. 5 and 6, the thermal mismatch between gallium nitride-based layers and the underlying semiconductor substrate material 202 (e.g., silicon) can cause tensile or compressive strain in the structure. It is desirable to limit the wafer bowing resulting from the deposition processing, in order to facilitate placement of the wafer structure in further processing machines following the epitaxial deposition, and to mitigate layer cracking, surface defects and other problems caused by wafer bow. Controlling the cool down rate of the processing chamber and the processed wafer structure after the high temperature epitaxial deposition facilitates control over wafer bowing. FIG. 5 shows an exaggerated view of the wafer structure, including the substrate 202 and the uppermost stack layer 210 during fabrication of the integrated circuit 200 with a concave upper surface, referred to herein as “positive” bowing. FIG. 6 shows bowing in the opposite direction to provide a convex upper surface at the deposited layer 210, referred to herein as “negative” bowing.

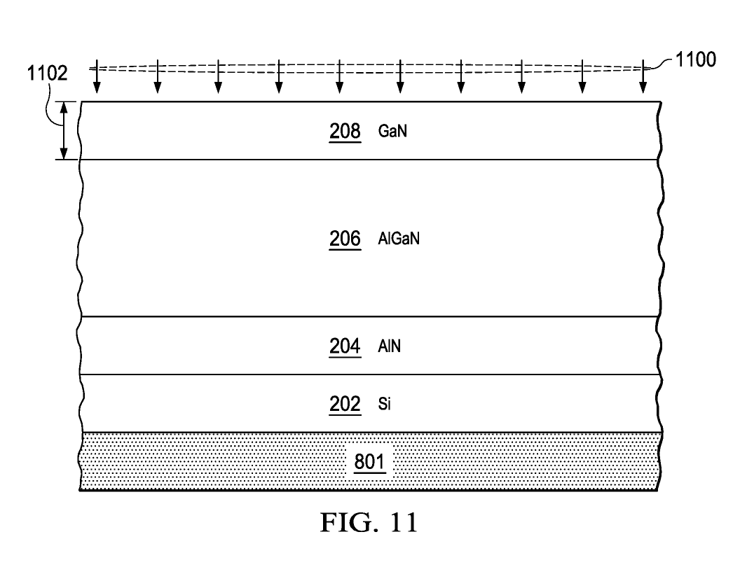

FIG. 7 provides a graph 700 that shows wafer bow as a function of time during the epitaxial deposition processing and controlled cool down according to the method of FIG. 1. The vertical axis in FIG. 7 shows the amount of bow in the positive or negative direction (FIG. 5 or FIG. 6) as a percentage of the vertical amount of bowing relative to the total structure thickness. The graph 700 illustrates bow curves 702, 704 and 706 for three different example implementations of the processing method 100 of FIG. 1. In these examples, the wafer bow increases in the positive direction (i.e., becomes more convex as in FIG. 5) during the high temperature AlN deposition during the time period 708, and the bow decreases in the AlGaN deposition period 710. The bow reverses to concave (negative values as in FIG. 6) during the GaN deposition period 712. The substrate wafer 202 reaches an extreme negative (concave) bow at the completion of the deposition period 712. The controlled cool down period 714 reverses the bow back toward zero through controlling the chamber and substrate cooling temperatures (112 in FIG. 1).

The temperature control at 112 (1300 in FIG. 13) cools the substrate 202 and the formed layers 204-210 at a controlled cooling rate. In one example, the controlled cooling rate is less than or equal to 1 degree C. per second. This range has been found to significantly reduce wafer bow compared to uncontrolled cooling at higher rates of 2-3 degrees C. per second. In one example, the controlled cooling rate is 0.5 to 1 degree C. per second. In certain examples, a multi-step controlled cool down is implemented at 112 in FIG. 1 using a cool down rate less than 0.5 to 1.0 degrees per second from approximately 1150 degrees C. to 500 degrees C., followed by a controlled cool down at a rate of 0.2 to 0.6 degrees C. per second from 500 to 200 degrees C. In certain implementations, the processing chamber controls the cooling rate at 112 in FIG. 1 by applying heat to the substrate 202 to control 112 the temperature of the processing chamber after forming the surface sub layers 208-210. Moreover, certain implementations further include providing nitrogen gas in the processing chamber while cooling the substrate 202 to mitigate surface defects in the deposited buffer and surface layers.

Referring also to FIG. 14, certain implementations of the method 100 include selecting the semiconductor substrate 202 having a resistivity in a predetermined range at 101 in FIG. 1. A graph 1400 in FIG. 14 shows wafer bow as a function of time during the epitaxial deposition processing and subsequent controlled cool down according to the method 100. The graph 1400 includes example wafer bow curves 1402, 1404 and 1406 for three different example starting wafer resistivity values with bow variation during the above described processing phases or periods 708, 710, 712 and 714 for equal wafer stack thicknesses. In certain examples, the starting wafer substrate is chosen at 101 to have a resistivity in a range is 1.0 to 10 mohms per square. The curve 1402 represents post deposition wafer bow for wafer substrates 202 with intermediate resistivity values in the range of 2.0 to 6.0 mohms per square. The curves 1404 and 1406 post deposition wafer bow for wafer substrates 202 with intermediate range resistivity values outside this range. Presently disclosed examples provide for controlled cool down after high temperature buffer and surface layer depositions for bow control, alone or in combination with engineering thickness and/or composition of the individual films in GaN based epitaxial stack, and intelligent selection of starting substrate wafers 202 in a predetermined resistivity range to control wafer bow from convex to concave and vice versa.

The above examples are merely illustrative of several possible embodiments of various aspects of the present disclosure, wherein equivalent alterations and/or modifications will occur to others skilled in the art upon reading and understanding this specification and the annexed drawings. Modifications are possible in the described embodiments, and other embodiments are possible, within the scope of the claims.

1. A method to fabricate an epitaxial layer stack for a transistor, comprising:
providing a semiconductor substrate in a processing chamber;
forming an aluminum nitride layer on the substrate in the processing chamber;
forming an aluminum gallium nitride layer on the aluminum nitride layer in the processing chamber;
forming a surface layer on the aluminum gallium nitride layer in the processing chamber; and
controlling a temperature of the processing chamber after forming the surface layer to cool the substrate and the formed layers at a controlled cooling rate,
wherein cooling the substrate and the formed layers at the controlled cooling rate results in the aluminum nitride layer, the aluminum gallium nitride layer and the surface layer being crack-free.

2. The method of claim 1, wherein the controlled cooling rate is less than or equal to 1° C./s.

3. The method of claim 2, wherein the controlled cooling rate is 0.5 to 1° C./s.

4. The method of claim 2, comprising applying heat to the substrate to control the temperature of the processing chamber after forming the surface layer.

5. The method of claim 4, further comprising providing nitrogen gas in the processing chamber while cooling the substrate.

6. The method of claim 2, further comprising providing nitrogen gas in the processing chamber while cooling the substrate.

7. The method of claim 2, further comprising controlling the temperature of the processing chamber to 1000° C. or more while forming the aluminum nitride layer, the aluminum gallium nitride layer and the surface layer.

8. The method of claim 1, comprising applying heat to the substrate to control the temperature of the processing chamber after forming the surface layer.

9. The method of claim 1, further comprising providing nitrogen gas in the processing chamber while cooling the substrate.

10. The method of claim 1, further comprising controlling the temperature of the processing chamber to 1000° C. or more while forming the aluminum nitride layer, the aluminum gallium nitride layer and the surface layer.

11. The method of claim 1, wherein the aluminum gallium nitride layer on the aluminum nitride layer is formed as a multilayer structure by:
forming a first aluminum gallium nitride sublayer to a first thickness with a first aluminum content on the aluminum nitride layer in the processing chamber;
forming a second aluminum gallium nitride sublayer to a second thickness with a second aluminum content on the first aluminum gallium nitride sublayer in the processing chamber, the second thickness being greater than the first thickness, and the second aluminum content being less than the first aluminum content; and
forming a third aluminum gallium nitride sublayer to a third thickness with a third aluminum content on the second aluminum gallium nitride sublayer in the processing chamber, the third thickness being greater than the second thickness, and the third aluminum content being less than the second aluminum content.

12. The method of claim 11, wherein forming the surface layer comprises:
forming a first gallium nitride layer on the aluminum gallium nitride layer in the processing chamber; and
forming an additional aluminum gallium nitride layer on the first gallium nitride layer in the processing chamber.

13. The method of claim 1, wherein forming the surface layer comprises:
forming a first gallium nitride layer on the aluminum gallium nitride layer in the processing chamber; and
forming an additional aluminum gallium nitride layer on the first gallium nitride layer in the processing chamber.

14. The method of claim 13, wherein the first gallium nitride layer is formed as a multilayer gallium nitride structure.

15. The method of claim 1, further comprising selecting the semiconductor substrate having a resistivity in a range of about 1.0 mΩ/□ to about 10 mΩ/□.

16. The method of claim 15, wherein the predetermined range is 2.5Ω/□ to 4.5Ω/□.

17. A method to fabricate an integrated circuit, comprising:
forming an aluminum nitride layer on a silicon substrate in a processing chamber;
forming an aluminum gallium nitride layer on the aluminum nitride layer in the processing chamber;
forming a surface layer on the aluminum gallium nitride layer in the processing chamber;
controlling a temperature of the processing chamber after forming the surface layer to cool the substrate and the formed layers at a controlled rate, thereby forming a crack-free aluminum nitride layer, aluminum gallium nitride layer and surface layer; and
fabricating at least one transistor, including a source and a drain formed in the surface layer.

18. The method of claim 17, comprising applying heat to the substrate to control the temperature of the processing chamber to cool the substrate and the formed layers at the controlled rate of less than or equal to 1° C./s after forming the surface layer.

19. The method of claim 17, further comprising selecting the semiconductor substrate having a resistivity in a range of about 1.0 mΩ/□ to about 10 mΩ/□.

20. (canceled)

21. The method of claim 17, further comprising forming the aluminum gallium nitride as a plurality sublayers with progressively lower sublayer aluminum content and progressively greater sublayer thickness
